(19) United States
(12) Patent Application Publication
(10) Pub. No.: US 2020/0011610 A1
(43) Pub. Date: Jan. 9, 2020

(54) HEAT DISSIPATION MODULE

(71) Applicant: Acer Incorporated, New Taipei City (TW)

(72) Inventors: Chun-Chieh Wang, New Taipei City (TW); Wen-Neng Liao, New Taipei City (TW); Cheng-Wen Hsieh, New Taipei City (TW); Yu-Ming Lin, New Taipei City (TW); Ming-Fei Tsai, New Taipei City (TW)

(73) Assignee: Acer Incorporated, New Taipei City (TW)

(21) Appl. No.: 16/503,605

(22) Filed: Jul. 4, 2019

(30) Foreign Application Priority Data
Jul. 5, 2018 (TW) 107123377

(51) Int. Cl. F28D 15/02; F28D 15/06; H01L 23/427; G06F 1/20; H01L 23/473

(52) U.S. Cl. CPC F28D 15/0266; F28D 15/06; H01L 23/427; G06F 2200/201; G06F 1/20; H01L 23/473; F28D 2015/0216; F28D 15/0275

(57) ABSTRACT

A portable electronic device having a heat source is provided with a suitable heat dissipation module. The heat dissipation module includes an evaporator, at least one pipe, a working fluid, and at least one check valve. The evaporator thermally contacts the heat source to transmit the heat generated by the heat source to the evaporator. The pipe is connected to the evaporator to form at least one loop, and the working fluid is filled in the loop. The working fluid absorbs and dissipates the heat in the loop to generate a phase change. The check valve is disposed at the loop and provides at least one recirculation channel in the same direction as the first direction and opposite to a second direction to block the working fluid from flowing in the second direction. The first and the second directions are opposite to each other.

### CROSS-REFERENCE TO RELATED APPLICATION

This application claims the priority benefit of Taiwan application serial no. 107123377, filed on Jul. 5, 2018. The entirety of the above-mentioned patent application is hereby incorporated by reference herein and made a part of this specification.

### BACKGROUND OF THE INVENTION

### Field of the Invention

The invention relates to a heat dissipation module.

### Description of Related Art

As technology advances, portable electronic devices are developed towards miniaturization. For example, a thin and light notebook computer, a tablet computer (tablet PC) or a smart phone has a miniaturized appearance that is suitable for a user to carry with and operate. Additionally, in order to enhance processing efficiency of the tablet PC, performance of a central processing unit (CPU) of a motherboard is also enhanced along therewith. However, as a result, a great amount of heat may be likely generated, and this may usually cause malfunction to circuits or electronic components of the electronic device due to over-heat, which is really inconvenient.

Generally, heat dissipation modules that may be disposed in the electronic devices include air-cooling heat dissipation modules or water-cooling heat dissipation modules, wherein the water-cooling heat dissipation modules have preferable heat dissipation efficiency. Nevertheless, under the trend that the portable electronic devices are designed and developed toward miniaturization, how to dispose a corresponding heat dissipation module in a limited space in a machine body as well as maintain the heat dissipation efficiency at the same time is indeed a subject that should be considered and solved by people in this field.

Moreover, as use states of the portable electronic device vary, a flowing situation of a working fluid in a loop of an air-cooling heat dissipation module or a water-cooling heat dissipation module is influenced. For example, the working fluid may become instable due to the influence by the gravity, but the use state of the portable electronic device cannot be restricted in this way. Additionally, in order to prevent the working fluid from being influenced by the gravity, it is necessary to design a corresponding step-formed structure for various use states of the portable electronic device. If so, an inevitable result that the appearance volume of the portable electronic device is infinitely enlarged may occur, which is unfavorable for the trend and idea toward miniaturization.

Accordingly, how to prevent the flowing mode of the working fluid from being influenced due to the heat dissipation module in different use states to improve the heat dissipation efficiency is a subject that relevant technicians have to consider and solve.

### SUMMARY OF THE INVENTION

The invention provides a heat dissipation module capable of restricting a flowing direction of a working fluid in a loop by a check valve, thereby overcoming the influence caused to the working fluid due to use states of a portable electronic device.

A heat dissipation module of the invention is suitable for a portable electronic device. The portable electronic device has a heat source. The heat dissipation module includes an evaporator, at least one pipe, a working fluid, and at least one check valve. The evaporator thermally contacts the heat source to transmit the heat generated by the heat source to the evaporator. The pipe is connected to the evaporator to form at least one loop. The working fluid is filled in the loop. The working fluid in a liquid phase absorbs the heat and is converted into the working fluid in a vapor phase flowing from the evaporator to the pipe, and the working fluid in the vapor phase dissipates the heat in the pipe and is converted into the working fluid in the liquid phase flowing into the evaporator. The check valve is disposed at the loop to restrict the working fluid to flow in a first direction in the loop. The check valve provides at least one recirculation channel in the same direction as the first direction and opposite to a second direction to block the working fluid from flowing in the second direction, wherein the first and the second directions are opposite to each other.

To sum up, the at least one check valve is disposed at the loop formed by connecting the evaporator with the pipe in the heat dissipation module, and because the check valve has the recirculation channel, the working fluid can be successfully restricted to flow in a single direction, namely, the working fluid is blocked from flowing reversely by the recirculation channel. In this way, the working fluid in the portable electronic device can overcome the influence in various degrees resulted in the working fluid from the gravity along with any used state of the portable electronic device. Namely, no matter whether the portable electronic device is used in a lying-flat state or a standing state, the gravity no longer influences the working fluid in the loop, thereby enhancing the heat dissipation efficiency of the heat dissipation module.

To make the above features and advantages of the invention more comprehensible, embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a portable electronic device according to an embodiment of the invention.

FIG. 2 is a partial top view of the heat dissipation module depicted in FIG. 1.

FIG. 3 is a cross-sectional view of a check valve according to another embodiment of the invention.

FIG. 4 is a schematic view of a check valve according to another embodiment of the invention.

### DESCRIPTION OF EMBODIMENTS

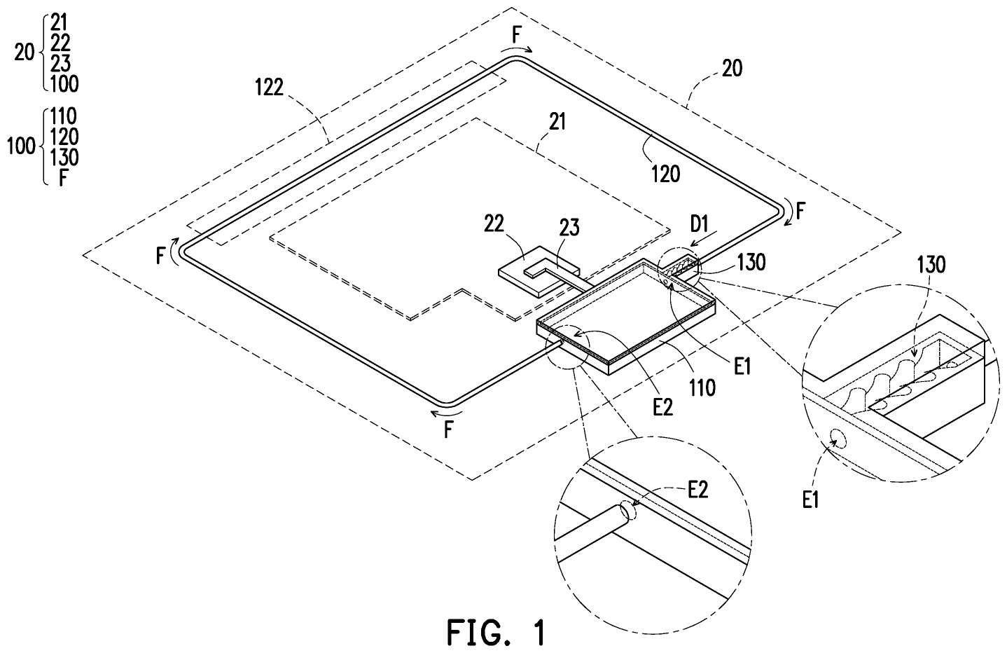

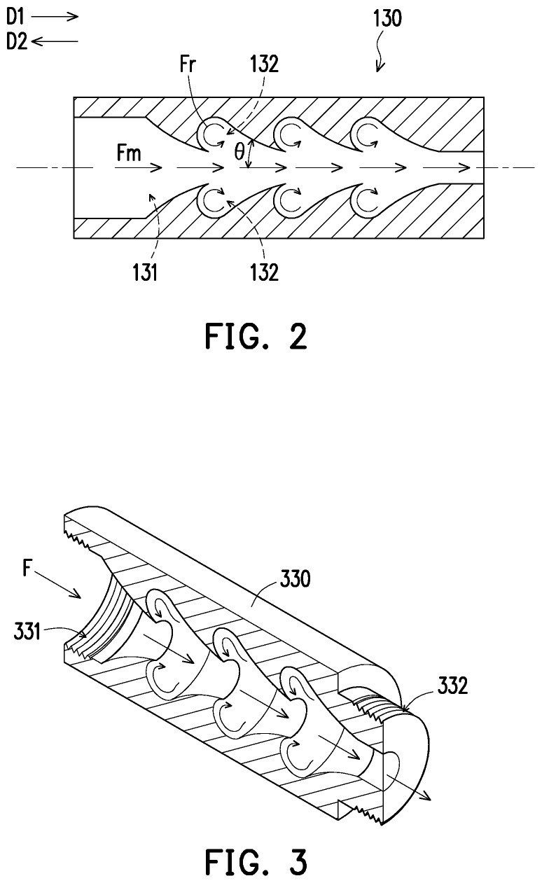

FIG. 1 is a schematic view of a portable electronic device according to an embodiment of the invention. FIG. 2 is a partial top view of the heat dissipation module depicted in FIG. 1. Referring to both FIG. 1 and FIG. 2, in the present embodiment, a portable electronic device 20 is, for example, a tablet computer (tablet PC) and includes a circuit board 21, a processor (which is a heat source 22) and a heat dissipation module 100. The heat dissipation module 100 includes an evaporator 110, a pipe 120, a working fluid F, and a check valve 130. In this case, the evaporator 110 thermally contacts the heat source 22, and with a heat pipe 23 substantially connected between the heat source 22 and the evaporator 110, the heat generated by the heat source 22 is transmitted to the evaporator 110 through the heat pipe 23. However, the structural corresponding relationship between the evaporator 110 and the heat source 22 is not limited in the invention. In another embodiment that is not shown, the evaporator may also directly structurally lean against the heat source, without the heat pipe for the heat transmission.

The pipe 120 is connected with an entrance E1 and an exit E2 of the evaporator 110 to form a loop. The working fluid F (which is represented by an arrow in the pipe 120 and the evaporator 110 in the drawing) is filled in the loop. In this case, after the heat is transmitted from the heat source 22 to the evaporator 110, the working fluid F in a liquid phase in the evaporator 110 absorbs the heat to generate a phase change (i.e., the working fluid F in the liquid phase is changed to a vapor phase) and then, flows from the evaporator 110 through the exit E2 to the pipe 120. Thereafter, the working fluid F in the vapor phase flowing through the pipe 120 dissipates the heat as the temperature drops, i.e., the working fluid F in the vapor phase is changed back to the working fluid F in the liquid phase at a condensing end 122 and again flows into the evaporator 110 through the entrance E1. Thereby, a two-phase flow circulatory system is formed by the change between the liquid phase and the vapor phase of the working fluid F, and the heat generated by the heat source 22 may be successfully dissipated out of the portable electronic device 20.

It should be noted that the check valve 130 of the present embodiment is connected between the pipe 120 and the entrance E1 of the evaporator 110, and the check valve 130 and the evaporator 110 substantially form an integrated structure. Namely, the check valve 130 and the evaporator 110 may be together manufactured, such that the check valve 130 may be considered as a branch of the main body of the evaporator 110, wherein the main body of the evaporator 110, the check valve 130 and the pipe 120 together form the loop.

The check valve 130 is employed to restrict the working fluid F to flow in a first direction D1 in the loop, thereby blocking the working fluid F from flowing in a second direction D2. The first direction D1 and the second direction D2 are opposite to each other. Furthermore, as illustrated in FIG. 2, the check valve 130 is a tesla valve including a mainstream portion 131 and recirculation portions 132. In the present embodiment, a mainstream portion 131 operated with a plurality of recirculation portions 132 is taken as an example. The recirculation portions 132 may cause the working fluid F to form at least one recirculation flow Fᵣ in addition to a mainstream flow Fₘ (in this case, a plurality of recirculation portions 132 forming a plurality of recirculation flows Fᵣ are taken as an example), and the recirculation flows Fᵣ formed by the recirculation portions 132 are substantially in the same direction as the first direction D1 of the mainstream flow Fₘ and opposite to the second direction D2. Thus, the flowing mode of the working fluid F in the second direction D2 in the loop is blocked by the mainstream flow Fₘ and the recirculation flows Fᵣ, such that the working fluid F is restricted to flow in the check valve 130 in only one way, i.e., the first direction D1 illustrated in the present embodiment. In this case, an inner diameter of the check valve 130 is less than or equal to 1 cm, which is favorable for the heat dissipation module 100 in the portable electronic device 20.

In this way, with the presence of the check valve 130, the working fluid F in either the liquid phase or the vapor phase is driven to flow in only one way (i.e., the first direction D1) in the loop illustrated in FIG. 1. Thus, when the portable electronic device 20 may present in a lying-flat state or a standing state due to different use states, the working fluid F may be prevented from being influenced in the manner described above. Therefore, the heat dissipation module 100 is capable of providing the heat dissipation effect as desired at any time.

In this case, the check valve 130 is disposed at the connection of the evaporator 110 and the pipe 120 and is located at the entrance E1. However, the invention is not limited thereto, in other embodiments that are not shown, the check valve 130 may also be disposed at the connection of the evaporator 110 and the pipe 120, but is located at the exit E2. Alternatively, the check valve 130 may also be disposed at the connection of the evaporator 110 and the pipe 120 and disposed at both the entrance E1 and the exit E2.

Referring again to FIG. 1 to FIG. 2, in the present embodiment, the integrally formed evaporator 110 and the check valve 130 are obtained through mechanically manufacturing with a block structure, but the invention is not limited thereto. FIG. 3 is a cross-sectional view of a check valve according to another embodiment of the invention. Referring to FIG. 3, the present embodiment is different from the previous embodiment in that a check valve 330 of the present embodiment is disposed at a condensing end of a pipe (i.e., a condensing end 122 of the pipe 120 described above) and is far away from the evaporator 110. In this case, the check valve 330 is disposed at the condensing end 122 to maintain the fluid power required for it to flow from (the condensing end 122 of) the pipe 120 into the evaporator 110 after the working fluid F is provided for heat dissipation (as the vapor phase is changed to the liquid phase).

Moreover, the check valve 330 of the present embodiment further has screw threads 331 and 332 for being successfully engaged with other parts of the pipe 120 (while corresponding screw threads capable of being screwed may also be disposed on other parts), which is equivalent to the check valve 330 being disposed at the pipe 120.

Accordingly, the location in the loop where the check valve is disposed is not limited in the invention, the check valve may be disposed at any location in the loop where the working fluid F flows to drive the working fluid F to flow in one way.

Referring again to FIG. 2, in the present embodiment, a pair of recirculation portions 132 are symmetrically disposed at two opposite sides of the mainstream portion 131 in the first direction D1, and the mainstream portion 131 and the recirculation portions 132 form a tapered contour (i.e., the tapering trend is in the same direction as the first direction D1), and the tapered contour causes the recirculation portions to form a tapered angle θ with respect to the mainstream portion 131, wherein the tapered angle θ is preferably 24 degrees (i.e., the recirculation portions 132 are symmetrical to each other at the two opposite sides of the mainstream portion 131 and have an included angle of 48 degrees).

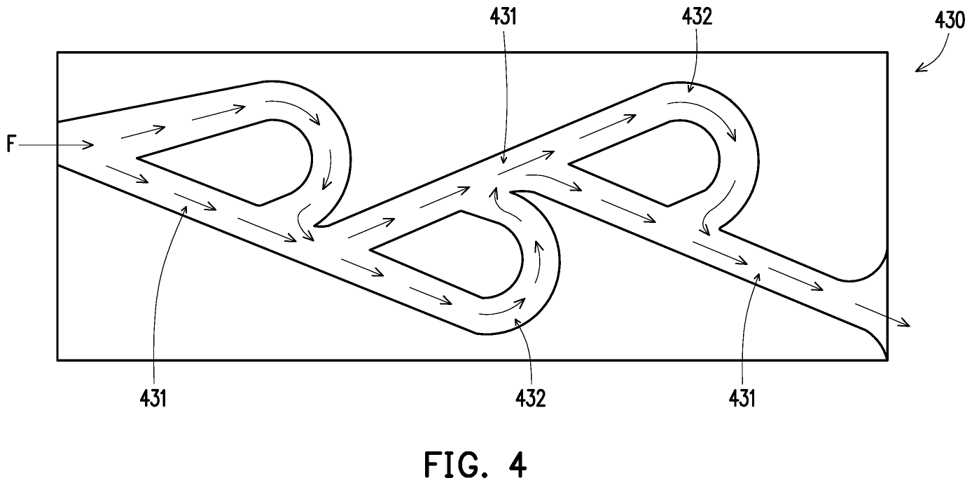

FIG. 4 is a schematic view of a check valve according to another embodiment of the invention. Referring to FIG. 4, the present embodiment is different from the embodiments described above in that in a check valve 430 of the present embodiment, a plurality of recirculation portions 432 are alternately disposed at one side of a mainstream portion 431 in the flowing direction of the working fluid F, the recirculation portions 432 and the mainstream portion 431 are structurally separated into different channels, which is different from the embodiment described above where the recirculation portions 132 and the mainstream portion 131 are located in the same channel. However, the recirculation flows resulted thereby may still effectively block the working fluid F from flowing reversely, thereby effectively maintain the one-way flowing mode.

Based on the above, in the embodiments of the invention, the at least one check valve is disposed at the loop formed by connecting the evaporator with the pipe in the heat dissipation module, and because the check valve has the recirculation channel, the working fluid can be successfully restricted to flow in a single direction, namely, the working fluid is blocked from flowing reversely by the recirculation channel. In this way, the working fluid in the portable electronic device can overcome the influence in various degrees resulted in the working fluid from the gravity along with any used state of the portable electronic device. Namely, no matter whether the portable electronic device is used in a lying-flat state or a standing state, the gravity no longer influences the working fluid in the loop, thereby enhancing the heat dissipation efficiency of the heat dissipation module.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A heat dissipation module, suitable for a portable electronic device having a heat source, comprising:
an evaporator, thermally contacting the heat source to transmit the heat generated by the heat source to the evaporator;
at least one pipe, connected to the evaporator to form at least one loop;
a working fluid, filled in the loop, wherein the working fluid in a liquid phase absorbs the heat and is converted into the working fluid in a vapor phase flowing from the evaporator to the pipe, and the working fluid in the vapor phase dissipates the heat in the pipe and is converted into the working fluid in the liquid phase flowing into the evaporator; and
at least one check valve, disposed at the loop to restrict the working fluid to flow in a first direction in the loop, wherein the check valve drives the working fluid to form at least one recirculation flow in the same direction as the first direction and opposite to a second direction to block the working fluid from flowing in the second direction in the loop, wherein the first and the second directions are opposite to each other.

2. The heat dissipation module according to claim 1, wherein the check valve is a tesla valve.

3. The heat dissipation module according to claim 1, wherein the check valve is disposed at a connection of the evaporator and the pipe.

4. The heat dissipation module according to claim 1, wherein the check valve is disposed at one of an exit and an entrance of the evaporator.

5. The heat dissipation module according to claim 1, wherein the check valve is disposed at the pipe.

6. The heat dissipation module according to claim 1, wherein the check valve is disposed at a condensing end of the loop.

7. The heat dissipation module according to claim 1, wherein the check valve has a mainstream portion and a recirculation portion,
wherein the recirculation portion is alternately disposed at one side of the mainstream portion in a flowing direction of the working fluid.

8. The heat dissipation module according to claim 1, wherein the check valve has the mainstream portion and a pair of recirculation portions,
wherein the recirculation portions are symmetrically disposed at two opposite sides of the mainstream portion in a flowing direction of the working fluid.

9. The heat dissipation module according to claim 8, the mainstream portion and the recirculation portions form a tapered contour in the flowing direction of the working fluid.

10. The heat dissipation module according to claim 9, wherein the tapered contour causes the recirculation portion to form a tapered angle with respect to the mainstream portion.
